(19) United States
(12) Patent Application Publication
(10) Pub. No.: US 2024/0274407 A1
(43) Pub. Date: Aug. 15, 2024

(54) PROCESSING SYSTEM AND METHODS TO CO-STRIKE PLASMA TO ENHANCE TUNGSTEN GROWTH INCUBATION DELAY

(71) Applicant: Applied Materials, Inc., Santa Clara, CA (US)

(72) Inventors: Peiqi WANG, Campbell, CA (US); Kelvin CHAN, San Ramon, CA (US); Kai WU, Palo Alto, CA (US); Mingrui ZHAO, Newark, CA (US); David PETERSON, Santa Clara, CA (US); Ping-Hwa HSIEH, Santa Clara, CA (US)

(21) Appl. No.: 18/168,168

(22) Filed: Feb. 13, 2023

(51) Int. Cl. H01J 37/32; H01L 21/02

(52) U.S. Cl. CPC H01J 37/32449; H01J 37/32458; H01J 37/32743; H01L 21/02315

(57) ABSTRACT

Embodiments herein are generally directed to electronic device manufacturing and, more particularly, to systems and methods for forming substantially void-free and seam-free tungsten features in a semiconductor device manufacturing scheme. In one embodiment, a substrate processing system features a processing chamber and a gas delivery system fluidly coupled to the processing chamber. The gas delivery system includes a first radical generator for use in a differential inhibition treatment process where the differential inhibition treatment process includes exposing a substrate to the effluent of a treatment plasma from a halogen free nitrogen-containing gas and a halogen-containing gas.

### BACKGROUND

### Field

Embodiments of the present invention generally relate to systems and methods used in electronic device manufacturing, and more particularly, to systems and methods used for forming tungsten features in a semiconductor device.

### Description of the Related Art

Tungsten (W) is widely used in integrated circuit (IC) device manufacturing to form conductive features where relatively low electrical resistance and relativity high resistance to electromigration are desired. For example, tungsten may be used as a metal fill material to form source contacts, drain contacts, metal gate fill, gate contacts, interconnects (e.g., horizontal features formed in a surface of a dielectric material layer), and vias (e.g., vertical features formed through a dielectric material layer to connect other interconnect features disposed there above and there below).

Due to its relativity low resistivity, tungsten is also commonly used to form bit lines and word lines used to address individual memory cells in a memory cell array of a three-dimensional NAND (3D NAND) device. 3D NAND structures include tiers of horizontal arrays that can be stacked by depositing layers in sequence. Channels can be formed through the stack of films and filled with tungsten. In some cases, the channel sidewall widths can vary between tiers. During filling the channel, the tungsten fill layer can deposit an upper portion of the channel quicker than a lower portion due to the varying channel sidewall widths and higher concentration of precursor gases used to deposit the tungsten fill layer. This can cause void formation within portions of the channels, particular for channels disposed in structures having two or more tiers, and particular for high aspect ratio features.

Accordingly, there is a need for processes to fill contact features that are free or substantially free of voids and seams and have low resistivity for various film thicknesses within channels in multi-tier structures.

### SUMMARY

Embodiments described herein generally relate to a systems and methods used in electronic device manufacturing. More specifically, embodiments of the present disclosure relate to systems and methods used for forming tungsten features in a semiconductor device.

In an embodiment, a substrate processing system is provided. The substrate processing system comprises a processing chamber with a chamber lid assembly, one or more chamber sidewalls, and a chamber base that collectively defines a processing volume. A gas delivery system is fluidly coupled to the processing chamber and includes a first radical generator, a second radical generator, and a non-transitory computer readable medium having instructions stored to perform a method of processing a plurality of substrates. The method includes receiving a substrate into the processing volume, forming a first tungsten nucleation layer on the substrate, exposing the substrate to an activated treatment gas wherein the activated treatment gas includes an effluent of a treatment plasma formed in the first radical generator formed of a halogen-free gas and a halogen-containing gas, exposing the substrate to a first tungsten-containing precursor and a first reducing agent to deposit a tungsten gapfill material, and transferring the substrate out of the processing volume.

In another embodiment, a gas delivery system for processing a substrate is provided. The gas delivery system comprises a first radical generator, a second radical generator, and a non-transitory computer readable medium having instructions stored to perform a method of processing a plurality of substrates. The method includes receiving a substrate into a processing volume of a processing chamber fluidly coupled to the gas delivery system, forming a first tungsten nucleation layer on the substrate, exposing the substrate to an activated treatment gas where the activated treatment gas includes an effluent of a treatment plasma formed in the first radical generator of a substantially halogen-free gas and a halogen-containing gas, exposing the substrate to a first tungsten-containing precursor and a first reducing agent to deposit a tungsten gapfill material, and transferring the substrate out of the processing volume.

In yet another embodiment, a method of processing a substrate is provided. The method comprises receiving the substrate into a processing volume of a processing chamber, forming a first tungsten nucleation layer on the substrate, exposing the substrate to an activated treatment gas where the activated treatment gas includes an effluent of a treatment plasma formed of a halogen-free gas and a halogen-containing gas, and exposing the substrate to a first tungsten-containing precursor and a first reducing agent.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of the scope of the disclosure, as the disclosure may admit to other equally effective embodiments.

FIG. 1A is a schematic side view of a processing system that may be used to implement the methods set forth herein, according to an embodiment.

FIG. 1B is a close-up sectional view of a portion of the processing system shown in FIG. 1A, according to an embodiment.

FIG. 2 is a diagram illustrating a substrate processing method, according to one embodiment, which may be performed using the processing system of FIGS. 1A-1B.

FIGS. 3A, 3B, 3C, and 3D are schematic sectional views of a portion of a substrate illustrating various aspects of the method set forth in FIG. 2.

FIG. 4 is a schematic plan view of an exemplary multi-chamber processing system that may be used to perform the methods set forth herein, according to one embodiment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments herein are generally directed electronic device manufacturing and, more particularly, to systems and methods for forming low resistivity tungsten features in a semiconductor device manufacturing scheme.

Typically, the tungsten features in an integrated circuit (IC) device are formed using a damascene (metal inlay) manufacturing process flow. The damascene process flow begins with depositing a layer of dielectric material on the surface of the substrate, patterning the dielectric layer to form a plurality of openings, and depositing a layer of tungsten material onto the surface of the dielectric layer to fill the openings. Often, a layer of barrier or adhesion material, such as titanium nitride (TiN), is deposited to line the openings before deposition of the tungsten layer. Deposition of the barrier layer and tungsten layer creates an overburden of barrier and tungsten material on the field of the substrate, which is then removed by use of a chemical mechanical polishing (CMP) process.

The CMP process uses a combination of chemical and mechanical activity to planarize the tungsten overburden from the field, which is provided, at least in part, by a polishing fluid. Typical tungsten CMP polishing fluids comprise an aqueous solution that includes one or more chemically active components and suspended abrasive components, e.g., nanoparticles, to form a polishing slurry. The chemically active components soften the tungsten surface, e.g., by oxidizing the surface to form a thin layer of tungsten oxide, and the abrasive components polish (remove) the tungsten oxide to expose tungsten there beneath. The cycle of oxidation and polishing continues throughout the CMP process until the tungsten overburden is cleared from the field of the dielectric layer leaving the embedded tungsten features.

Typically, tungsten deposited using conventional methods is highly conformal to the underlying patterned surface. Unfortunately, as device features shrink and aspect ratios increase, the formation of undesirable voids and seams in tungsten features formed using conformal tungsten deposition methods is largely unavoidable. The resulting undesirable voids and seams may cause device performance and reliability problems or even device failure.

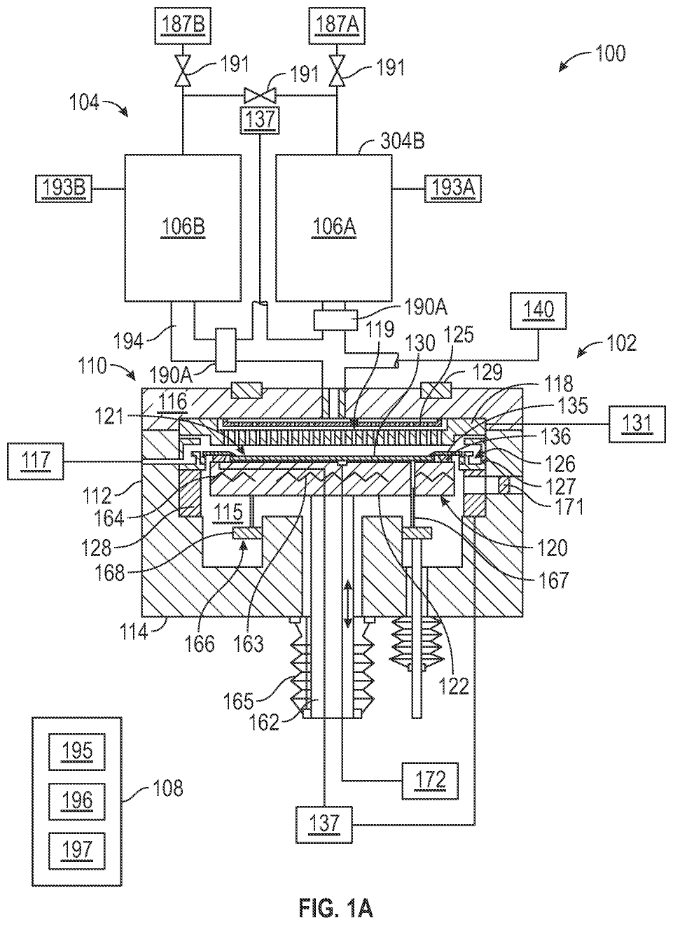

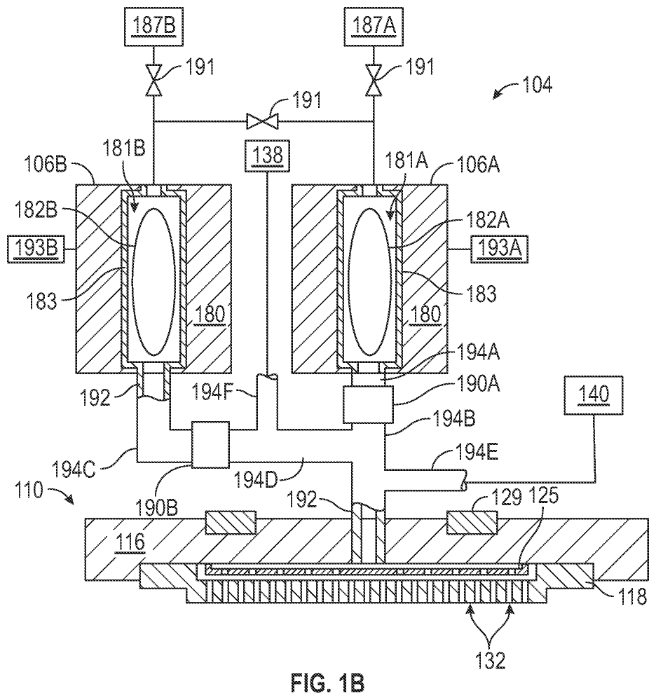

As discussed below, the use of assigned plasma sources for respective inhibition and chamber cleaning processes provides improved processing stability for the inhibition treatments when compared to a processing system using a common plasma source for both. Thus, embodiments herein beneficially provide a relativity low-cost and high throughput, single-chamber solution for seam-suppressed tungsten gapfill, such as the processing system illustrated in FIGS. 1A-1B.

FIGS. 1A-1B schematically illustrate a processing system 100 that may be used to perform the bottom-up tungsten gapfill substrate processing methods described herein. Here, the processing system is configured to provide the different processing conditions desired for each of a nucleation process, inhibition treatment process, selective gapfill process, and overburden deposition process within a single processing chamber 102, i.e., without transferring a substrate between a plurality of processing chambers.

As shown in FIG. 1A, the processing system 100 includes the processing chamber 102, a gas delivery system 104 fluidly coupled to the processing chamber 102, and a system controller 108. The processing chamber 102 (shown in cross-section in FIG. 1A) includes a chamber lid assembly 110, one or more sidewalls 112, and a chamber base 114, which collectively define a processing volume 115. The processing volume 115 is fluidly coupled to an exhaust 117, such as one or more vacuum pumps, used to maintain the processing volume 115 at sub-atmospheric conditions and to evacuate processing gases and processing by-products therefrom.

The chamber lid assembly 110 includes a lid plate 116 and a showerhead 118 coupled to the lid plate 116 to define a gas distribution volume 119 therewith. Here, the lid plate 116 is maintained at a desired temperature using one or more heaters 129 thermally coupled thereto. The showerhead 118 faces a substrate support assembly 120 disposed in the processing volume 115. As discussed below, the substrate support assembly 120 is configured to move a substrate support 122, and thus a substrate 130 disposed on the substrate support 122, between a raised substrate processing position (as shown) and a lowered substrate transfer position (not shown). When the substrate support assembly 120 is in the raised substrate processing position, the showerhead 118 and the substrate support 122 define a processing region 121.

Here, the gas delivery system 104 is fluidly coupled to the processing chamber 102 through a gas inlet 123 (FIG. 1B) that is disposed through the lid plate 116. Processing or cleaning gases delivered, by use of the gas delivery system 104, flow through the gas inlet 123 into the gas distribution volume 119 and are distributed into the processing region 121 through a plurality of openings 132 (FIG. 1B) in the showerhead 118. In some embodiments, the chamber lid assembly 110 further includes a perforated blocker plate 125 disposed between the gas inlet 123 and the showerhead 118. In those embodiments, gases flowed into the gas distribution volume 119 are first diffused by the blocker plate 125 to, together with the showerhead 118, provide a more uniform or desired distribution of gas flow into the processing region 121.

Here, processing gases and processing by-products are evacuated radially outward from the processing region 121 through an annular channel 126 that surrounds the processing region 121. The annular channel 126 may be formed in a first annular liner 127 disposed radially inward of the one or more sidewalls 112 (as shown) or may be formed in the one or more sidewalls 112. In some embodiments, the processing chamber 102 includes one or more second liners 128, which are used to protect the interior surfaces of the one or more sidewalls 112 or chamber base 114 from corrosive gases or undesired material deposition.

In some embodiments, a purge gas source 137 in fluid communication with the processing volume 115 is used to flow a chemically inert purge gas, such as argon (Ar), into a region disposed beneath the substrate support 122, e.g., through the opening in the chamber base 114 surrounding a support shaft 162. The purge gas may be used to create a region of positive pressure below the substrate support 122 (when compared to the pressure in the processing region 121) during substrate processing. Typically, purge gas introduced through the chamber base 114 flows upwardly therefrom and around the edges of the substrate support 122 to be evacuated from the processing volume 115 through the annular channel 126. The purge gas reduces undesirable material deposition on surfaces beneath the substrate support 122 by reducing or preventing the flow of material precursor gases thereinto.

Here, the substrate support assembly 120 includes the movable support shaft 162 that sealingly extends through the chamber base 114, such as being surrounded by a bellows 165 in the region below the chamber base 114, and the substrate support 122, which is disposed on the movable support shaft 162. To facilitate substrate transfer to and from the substrate support 122, the substrate support assembly 120 includes a lift pin assembly 166 comprising a plurality of lift pins 167 coupled to or disposed in engagement with a lift pin hoop 168. The plurality of lift pins 167 are movably disposed in openings formed through the substrate support 122. When the substrate support 122 is disposed in a lowered substrate transfer position (not shown), the plurality of lift pins 167 extend above a substrate receiving surface of the substrate support 122 to lift a substrate 130 therefrom and provide access to a backside (non-active) surface of the substrate 130 by a substrate handler (not shown). When the substrate support 122 is in a raised or processing position (as shown), the plurality of lift pins 167 recede beneath the substrate receiving surface of the substrate support 122 to allow the substrate 130 to rest thereon.

Here, the substrate 130 is transferred to and from the substrate support 122 through a door 171, e.g., a slit valve disposed in one of the one or more sidewalls 112. Here, one or more openings in a region surrounding the door 171, e.g., openings in a door housing, are fluidly coupled to a purge gas source 137, e.g., an Ar gas source. The purge gas is used to prevent processing and cleaning gases from contacting or degrading a seal surrounding the door, thus extending the useful lifetime thereof.

Here, the substrate support 122 is configured for vacuum chucking where the substrate 130 is secured to the substrate support 122 by applying a vacuum to an interface between the substrate 130 and the substrate receiving surface. The vacuum is applied by use of a vacuum source 172 fluidly coupled to one or more channels or ports formed in the substrate receiving surface of the substrate support 122. In other embodiments, e.g., where the processing chamber 102 is configured for direct plasma processing, the substrate support 122 may be configured for electrostatic chucking. In some embodiments, the substrate support 122 includes one or more electrodes (not shown) coupled to a bias voltage power supply (not shown), such as a continuous wave (CW) RF power supply or a pulsed RF power supply, which supplies a bias voltage thereto.

As shown, the substrate support assembly 120 features a dual-zone temperature control system to provide independent temperature control within different regions of the substrate support 122. The different temperature-controlled regions of the substrate support 122 correspond to different regions of the substrate 130 disposed thereon. Here, the temperature control system includes a first heater 163 and a second heater 164. The first heater 163 is disposed in a central region of the substrate support 122, and the second heater 164 is disposed radially outward from the central region to surround the first heater 163. In other embodiments, the substrate support 122 may have a single heater or more than two heaters.

In some embodiments, the substrate support assembly 120 further includes an annular shadow ring 135, which is used to prevent undesired material deposition on a circumferential bevel edge of the substrate 130. During substrate transfer to and from the substrate support 122, i.e., when the substrate support assembly 120 is disposed in a lowered position (not shown), the shadow ring 135 rests on an annular ledge within the processing volume 115. When the substrate support assembly 120 is disposed in a raised or processing position, the radially outward surface of the substrate support 122 engages with the annular shadow ring 135 so that the shadow ring 135 circumscribes the substrate 130 disposed on the substrate support 122. Here, the shadow ring 135 is shaped so that a radially inward facing portion of the shadow ring 135 is disposed above the bevel edge of the substrate 130 when the substrate support assembly 120 is in the raised substrate processing position.

In some embodiments, the substrate support assembly 120 further includes an annular purge ring 136 disposed on the substrate support 122 to circumscribe the substrate 130. In those embodiments, the shadow ring 135 may be disposed on the purge ring 136 when the substrate support assembly 120 is in the raised substrate processing position. Typically, the purge ring 136 features a plurality of radially inward facing openings that are in fluid communication with the purge gas source 137. During substrate processing, a purge gas flows into an annular region defined by the shadow ring 135, the purge ring 136, the substrate support 122, and the bevel edge of the substrate 130 to prevent processing gases from entering the annular region and causing undesired material deposition on the bevel edge of the substrate 130.

In some embodiments, the processing chamber 102 is configured for direct plasma processing. In those embodiments, the showerhead 118 may be electrically coupled to a first power supply 131, such as an RF power supply, which supplies power to ignite and maintain a plasma of processing gases flowed into the processing region 121 through capacitive coupling therewith. In some embodiments, the processing chamber 102 comprises an inductive plasma generator (not shown), and a plasma is formed through inductively coupling an RF power to the processing gas.

Here, the processing system 100 is advantageously configured to perform each of the tungsten nucleation, inhibition treatment, and bulk tungsten deposition processes of a void-free and seam-free tungsten gapfill process scheme without removing the substrate 130 from the processing chamber 102. The gases used to perform the individual processes of the gapfill process scheme, and to clean residues from the interior surfaces of the processing chamber, are delivered to the processing chamber 102 using the gas delivery system 104 fluidly coupled thereto.

Generally, the gas delivery system 104 includes one or more remote plasma sources, here the first and second radical generator 106A-B, a deposition gas source 140, and a conduit system 194 (e.g., the plurality of conduits 194A-F in FIG. 1B) fluidly coupling the radical generators 106A-B and the deposition gas source 140 to the lid assembly 110. The gas delivery system 104 further includes a plurality of isolation valves, here the first and second valves 190A-B, respectively disposed between the radical generators 106A-B and the lid plate 116, which may be used to fluidly isolate each of the radical generators 106A-B from the processing chamber 102 and from one another.

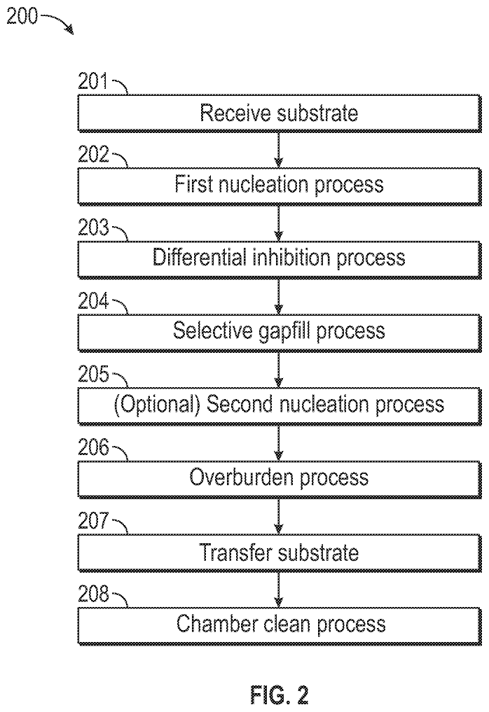

Here, each of the radical generators 106A-B features a chamber body 180 that defines the respective first and second plasma chamber volumes 181A-B (FIG. 1B). Each of the radical generators 106A-B is coupled to a respective power supply 193A-B. The power supplies 193A-B are used to ignite and maintain a plasma 182A-B of gases delivered to the plasma chamber volumes 181A-B from a corresponding first or second gas source 187A-B fluidly coupled thereto. In some embodiments, the first radical generator 106A generates radicals used in the differential inhibition process of activity 203 (FIG. 2). For example, the first radical generator 106A may be used to ignite and maintain a treatment plasma 182A from a non-halogen-containing gas mixture and a halogen-containing gas mixture delivered to the first plasma chamber volume 181A from the first gas source 187A and the second gas source 187B. The second radical generator 106B may be used to generate cleaning radicals used in a chamber clean process, e.g., activity 208 (FIG. 2) by igniting and maintaining a cleaning plasma from a halogen-containing gas mixture delivered to the second plasma chamber volume 181B from the second gas source 187B. The first gas source 187A may provide a non-halogen containing gas, such as N₂, mixed with a carrier gas, such as Ar, to the first radical generator 106A while the second gas source 187B may provide a halogen-containing gas, such as NF₃, mixed with a carrier gas, such as Ar, to the first radical generator 106A. For 500 sccm of Ar, the first gas source may provide at least 1 sccm of N₂, preferably at least 2 sccm of N₂, preferably at least 3 sccm of N₂, preferably at least 5 sccm of N₂, preferably at least 10 sccm of N₂ to the first radical generator 106A. The second gas source 187B may simultaneously provide between 0.3 sccm and 20 sccm of NF₃, preferably between 0.5 sccm and 5 sccm of NF₃, preferably between 1 sccm and 3 sccm of NF₃ to the first radical generator 106A. Unwanted etching behavior during the treatment step begins to occur at large NF₃ concentrations (e.g., greater than 20 sccm) and may only be mitigated by lowering the overall flow of NF₃ rather than increasing N₂ flow to dilute the plasma.

Typically, nitrogen treatment radicals have a relativity short lifetime (when compared to halogen cleaning radicals) and may exhibit a relatively high sensitivity to recombination from collisions with surfaces in the gas delivery system 104 or with other species of the treatment plasma effluent. Thus, in embodiments herein, the first radical generator 106A is typically positioned closer to the gas inlet 123 than the second radical generator 106B, e.g., to provide a relatively shorter travel distance from the first plasma chamber volume 181A to the processing region 121.

In some embodiments, the first radical generator 106A is fluidly coupled to the second gas source 187B using a plurality of diverter valves 191, which are operable to direct the halogen-containing gas mixture from the second gas source 187B to the first plasma chamber volume 181A.

Suitable remote plasma sources which may be used for one or both of the radical generators 106A-B include radio frequency (RF) or very high radio frequency (VHRF) capacitively coupled plasma (CCP) sources, inductively coupled plasma (ICP) sources, microwave-induced (MW) plasma sources, electron cyclotron resonance (ECR) chambers, or high-density plasma (HDP) chambers.

As shown, the first radical generator 106A is fluidly coupled to the processing chamber 102 by use of first and second conduits 194A-B, which extend upwardly from the gas inlet 123 to connect with an outlet of the first plasma chamber volume 181A. A first valve 190A, disposed between the first and second conduits 194A-B, is used to selectively fluidly isolate the first radical generator 106A from the processing chamber 102 and the other portions of the gas delivery system 104. Typically, the first valve 190A is closed during the chamber clean process (activity 208) to prevent activated cleaning gases, e.g., halogen radicals, from flowing into the first plasma chamber volume 181A and damaging the surfaces thereof.

Here, the first radical generator 106A, the first and second conduits 194A-B, and the first valve 190A are arranged or configured so that the treatment plasma 182A is not disposed in a direct line-of-sight with the gas inlet 123, e.g., by having a bend in one or both of the conduits 194A-B. In other embodiments, the first plasma chamber volume 181A may be disposed in alignment with the gas inlet 123 to provide a direct line-of-sight from the treatment plasma 182A through the gas inlet 123 and into the processing chamber 102. The direct line-of-sight may beneficially reduce undesired recombination of the treatment radicals by reducing gas-phase collisions therebetween.

The second radical generator 106B is fluidly coupled to the second conduit 194B, and thus the processing chamber 102, by use of third and fourth conduits 194C-D. Here, the second radical generator 106B is selectively isolated from the processing chamber 102 and from the other portions of the gas delivery system 104 by use of a second valve 190B that is disposed between the third and fourth conduits 194C-D.

In some embodiments, the plasma-facing surfaces 183 of one or both of the plasma chamber volumes 181A-B are formed of a halogen-based plasma resistant material, such as aluminum oxide, aluminum nitride, silicon oxide, fused silica, quartz, sapphire, or combinations thereof. In some embodiments, the plasma-facing surfaces 183 of the plasma chamber volumes 181A-B comprise a tube or a liner formed of the halogen-plasma resistant material. In other embodiments, the plasma-facing surfaces 183 feature a coating or layer of a halogen-based plasma resistant material formed on the interior portions of the chamber body 180, such as an anodized aluminum layer formed on the interior portions of an aluminum chamber body. In some embodiments, one or more of the conduits 194A-F are lined with a low recombination dielectric material 192, such as fused silica, quartz, or sapphire, which desirably reduces recombination of the activated species in the remote plasma effluents as they are delivered to the processing chamber 102.

Here, deposition gases, e.g., tungsten-containing precursors and reducing agents, can be delivered from the deposition gas source 140 to the processing chamber 102 using a fifth conduit 194E. As shown, the fifth conduit 194E is coupled to the second conduit 194B at a location proximate to the gas inlet 123 so that the first and second valves 190A-B may be used to respectively isolate the first and second radical generators 106A-B from deposition gases introduced into the processing chamber 102. In some embodiments, the gas delivery system 104 further includes a sixth conduit 194F which is coupled to the fourth conduit 194D at a location proximate to the second valve 190B. The sixth conduit 194F is fluidly coupled to a bypass gas source 138, e.g., an argon (Ar) gas source, which may be used to periodically purge portions of the gas delivery system 104 of undesired residual cleaning, inhibition, or deposition gases.

Operation of the processing system 100 is facilitated by the system controller 108. The system controller 108 includes a programmable central processing unit, here a CPU 195, which is operable with a memory 196 (e.g., non-volatile memory) and support circuits 197. The CPU 195 is one of any form of general-purpose computer processor used in an industrial setting, such as a programmable logic controller (PLC), for controlling various chamber components and sub-processors. The memory 196, coupled to the CPU 195, facilitates the operation of the processing chamber. The support circuits 197 are conventionally coupled to the CPU 195 and comprise cache, clock circuits, input/output subsystems, power supplies, and the like, and combinations thereof coupled to the various components of the processing system 100 (or the multi-chamber processing system 800 of FIG. 8) to facilitate control of substrate processing operations therewith.

Here, the instructions in memory 196 are in the form of a program product, such as a program that implements the methods of the present disclosure. In one example, the disclosure may be implemented as a program product stored on computer-readable storage media for use with a computer system. The program(s) of the program product define functions of the embodiments (including the methods described herein). Thus, the computer-readable storage media, when carrying computer-readable instructions that direct the functions of the methods described herein, are embodiments of the present disclosure.

Advantageously, the processing system 100 described above may be used to perform each of the nucleation, inhibition, gapfill deposition, and overburden deposition processes of the method 200 set forth in FIG. 2, thus providing a single-chamber seam-free tungsten gapfill solution.

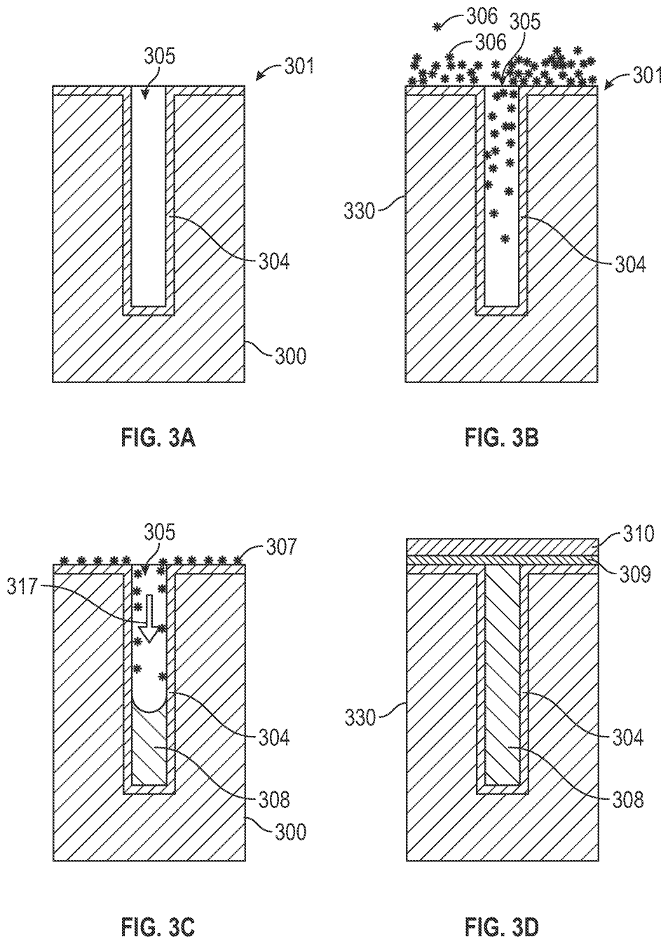

FIG. 2 is a diagram illustrating a method 200 of processing a substrate, according to an embodiment, which may be performed using the processing system 100. FIGS. 3A-3D are schematic sectional views of a portion of a substrate 300 illustrating aspects of the method 200 at different stages of a void-free and seam-free tungsten gapfill process scheme.

At activity 201, the method 200 includes receiving a substrate into the processing volume 115 of the processing chamber 102. At activity 202, the method 200 includes forming a nucleation layer 304 on the substrate using a nucleation process. A portion of an exemplary substrate 300 having the nucleation layer 304 formed thereon is schematically illustrated in FIG. 3A.

Here, the substrate 300 features a patterned surface 301 comprising a dielectric material layer 302 having a plurality of openings 305 (one shown) formed therein. In some embodiments, the plurality of openings 305 comprises one or a combination of high aspect ratio via or trench openings having a width of about 1 μm or less, such as about 800 nm or less, or about 500 nm or less, and a depth of about 2 μm or more, such as about 3 μm or more, or about 4 μm or more. In some embodiments, individual ones of the openings 305 may have an aspect ratio (depth to width ratio) of about 5:1 or more, such as about 10:1 or more, 15:1 or more, or between about 10:1 and about 100:1, such as between about 15:1 and about 100:1.

In some embodiments, the nucleation layer 304 is deposited using an atomic layer deposition (ALD) process. Typically, the ALD process includes repeating cycles of alternately exposing the substrate 300 to a tungsten-containing precursor, exposing the substrate 300 to a reducing agent, and purging the processing region 121 between the alternating exposures. Examples of suitable tungsten-containing precursors include tungsten halides, such as tungsten hexafluoride (WF₆), tungsten hexachloride (WCl₆), or combinations thereof. Examples of suitable reducing agents include hydrogen gas (H₂), boranes, e.g., B₂H₆, and silanes, e.g., SiH₄, Si₂H₆, or combinations thereof. In some embodiments, the tungsten-containing precursor comprises WF₆, and the reducing agent comprises B₂H₆, SiH₄, or a combination thereof. In some embodiments, the tungsten-containing precursor comprises an organometallic precursor and/or a fluorine-free precursor, e.g., MDNOW (methylcyclopentadienyl-dicarbonylnitrosyl-tungsten), EDNOW (ethylcyclopentadienyl-dicarbonylnitrosyl-tungsten), tungsten hexacarbonyl (W(CO)6), or combinations thereof.

During the nucleation process, the processing volume 115 is typically maintained at a pressure of less than about 120 Torr, such as of between about 900 m Torr and about 120 Torr, between about 1 Torr and about 100 Torr, or for example, between about 1 Torr and about 50 Torr. Exposing the substrate 300 to the tungsten-containing precursor includes flowing the tungsten-containing precursor into the processing region 121 from the deposition gas source 140 at a flow rate of more than about 10 sccm, such as between about 10 sccm and about 1000 sccm, such as between about 10 sccm and about 750 sccm, or between about 10 sccm and about 500 sccm. Exposing the substrate 300 to the reducing agent includes flowing the reducing agent into the processing region 121 from the deposition gas source 140 at a flow rate of between about 10 sccm and about 1000 sccm, such as between about 10 sccm and about 750 sccm. It should be noted that the flow rates for the various deposition and treatment processes described herein are for a processing system 100 configured to process a 300 mm diameter substrate. Appropriate scaling may be used for processing systems configured to process different-sized substrates.

Here, the tungsten-containing precursor and the reducing agent are each flowed into the processing region 121 for a duration of between about 0.1 seconds and about 10 seconds, such as between about 0.5 seconds and about 5 seconds. The processing region 121 may be purged between the alternating exposures by flowing an inert purge gas, such as argon (Ar), into the processing region 121 for a duration of between about 0.1 seconds and about 10 seconds, such as between about 0.5 seconds and about 5 seconds. The purge gas may be delivered from the deposition gas source 140 or from the bypass gas source 138. Typically, the repeating cycles of the nucleation process continue until the nucleation layer 304 has a thickness of between about 10 Å and about 150 Å, such as between about 10 Å and about 100 Å.

After activity 202 and before activity 203, there may be an optional conformal deposition process where a conformal tungsten layer is deposited on the first nucleation layer 304. After depositing a conformal tungsten layer, an optional second nucleation layer may deposited on the conformal tungsten layer.

At activity 203, the method 200 includes treating the nucleation layer 304 to inhibit tungsten deposition on a field surface of the substrate 300 and to form a differential inhibition profile in the plurality of openings 305 by use of a differential inhibition process. Forming the differential inhibition profile includes exposing the nucleation layer 304 to the activated species of a treatment gas, e.g., the treatment radicals 306 shown in FIG. 3B. In some embodiments, exposing the nucleation layer 304 to the treatment radicals 306 includes forming a treatment plasma 182A of a substantially halogen-free treatment gas mixture (i.e., first treatment gas mixture) and a halogen-containing treatment gas (i.e., second treatment gas mixture) using the first radical generator 106A, and flowing the effluent of the treatment plasma 182A into the processing region 121.

In some embodiments, the halogen-free treatment gas may include N₂, H₂, NH₃, NH₄, O₂, CH₄, or combinations thereof. In some embodiments, the halogen-free treatment gas comprises nitrogen, such as N₂, H₂, NH₃, NH₄, or a combination thereof, and the activated species comprise nitrogen radicals, e.g., atomic nitrogen. In some embodiments, the halogen-free treatment gas is combined with an inert carrier gas, such as Ar, He, or a combination thereof, to form a first treatment gas mixture. In one embodiment, the halogen-free treatment gas comprises N₂ and is combined with an inert gas, e.g., Ar, to form the first treatment gas mixture. In some embodiments, a concentration of the substantially halogen-free treatment gas in the first treatment gas mixture is between about 0.1 vol. % and about 50 vol. %, such as between about 0.5 vol. % and about 40 vol. %, between about 0.5 vol. % and about 30 vol. %, about 0.5 vol. % and about 20 vol. %, or, for example, between about 0.5 vol. % and about 10 vol. %, such as between about 0.5 vol. % and about 5 vol. %. In some embodiments, a flow rate of the halogen-free treatment gas into the first radical generator 106A is between about 1 sccm and about 3000 sccm, such as between about 1 sccm and about 2500 sccm, between about 1 sccm and about 2000 sccm, between about 1 sccm and about 1000 sccm, between about 1 sccm and about 500 sccm, between about 1 sccm and about 250 sccm between about 1 sccm and about 100 sccm, or between about 1 sccm and about 75 sccm, for example, between about 1 sccm and about 50 sccm.

In some embodiments, the halogen-containing treatment gas may include NF₃, N₂F₂, N₂F₄, or a combination thereof. In some embodiments, the halogen-containing treatment gas is combined with an inert carrier gas, such as Ar, He, or a combination thereof to form a second treatment gas mixture. In one embodiment, the halogen-containing treatment gas comprises NF₃ and is combined with an inert gas, e.g., Ar, (i.e., the second treatment gas mixture) to form the second treatment gas mixture. In some embodiments the flow rate of the halogen-containing treatment gas into the first radical generator 106A is between about 0.01 sccm and 20 sccm, between about 0.01 sccm and 10 sccm, between about 0.1 and 5 sccm, or between about 0.1 sccm and 3 sccm.

In other embodiments, the treatment radicals 306 may be formed using a plasma (not shown) which is ignited and maintained in a portion of the processing volume 115 that is separated from the processing region 121 by the showerhead 118, such as between the showerhead 118 and the lid plate 116. In those embodiments, the activated treatment gas (i.e., treatment gas comprising halogen-free treatment gas, halogen-containing treatment gas, and inert gas) may be flowed through an ion filter to remove substantially all ions therefrom before the treatment radicals 306 reach the processing region 121 and the surface of the substrate 300. In some embodiments, the showerhead 118 may be used as the ion filter. In other embodiments, a plasma used to form the treatment radicals is an in-situ plasma formed in the processing region 121 between the showerhead 118 and the substrate 300. In some embodiments, e.g., when using an in-situ treatment plasma, the substrate 300 may be biased to control the directionality and/or accelerate ions formed from the treatment gas, e.g., charged treatment radicals, towards the substrate surface.

Without intending to be bound by theory, it is believed that the activated nitrogen species (from treatment radicals 306) are incorporated into portions of the nucleation layer 304 by adsorption of the activated nitrogen species and/or by reaction with the metallic tungsten of the nucleation layer 304 to form a tungsten nitride (WN) surface. The adsorbed nitrogen and/or nitrided surface of the tungsten nucleation layer 304 desirably delays (inhibits) further tungsten nucleation and thus subsequent tungsten deposition thereon.

Generally, diffusion of the treatment radicals 306 into the plurality of openings 305 is controlled to cause a desired inhibition gradient within the feature openings 305. Here, diffusion of the treatment radicals 306 is controlled so that the tungsten growth inhibition effect decreases on the walls of the openings 305 with increasing distance from the field of the patterned surface 301 (FIGS. 3B-3C). As a result, tungsten nucleation is more easily established at locations at or near the bottom of the feature, and once established, tungsten growth (deposition of the gapfill material 308) within the openings 305 accelerates from the point of nucleation (e.g., from regions of no or low inhibition at the bottom of the opening 305) to provide for a bottom-up seamless tungsten gapfill. The direction of the inhibition gradient, from regions of higher inhibition to regions of no or lower inhibition, is shown by arrow 317 (FIG. 3C). Diffusion of the treatment radicals 306 into the openings 305 typically depends, at least in part, on the size and aspect ratios of the openings 305 and may be adjusted by controlling inter alia, the energy, flux, and, in some embodiments, the directionality of the treatment radicals 306 at the patterned surface 301.

In some embodiments, the inhibition treatment process includes exposing the substrate 300 to the treatment radicals 306 for a period of about 5 seconds or more, such as about 6 seconds or more, about 7 seconds or more, about 8 seconds or more, about 9 seconds or more, about 10 second or more, or between about 5 seconds and about 120 seconds, such as between about 5 seconds and about 90 seconds, or between about 5 seconds and about 60 seconds, or between about 5 seconds and about 30 seconds, for example, between about 5 seconds and about 20 seconds.

In some embodiments, the inhibition treatment process includes maintaining the processing volume 115 at a pressure of less than about 100 Torr while flowing the activated treatment gas thereinto. For example, during the inhibition treatment process, the processing volume 115 may be maintained at a pressure of less than about 75 Torr, such as less than about 50 Torr, less than about 15 Torr, less than about 15 Torr, or between about 0.5 Torr and about 120 Torr, such as between about 0.5 Torr and about 100 Torr, or between about 0.5 Torr and about 50 Torr, or for example, between about 1 Torr and about 10 Torr.

At activity 204, the method 200 includes selectively depositing a tungsten gapfill material 308 (FIGS. 3C-3D) into the plurality of openings 305 according to the differential inhibition profile provided by the inhibition treatment at activity 203. In one embodiment, the tungsten gapfill material 308 is formed using a low-stress chemical vapor deposition (CVD) process comprising concurrently flowing (co-flowing) a tungsten-containing precursor gas, and a reducing agent into the processing region 121 and exposing the substrate 300 thereto. The tungsten-containing precursor and the reducing agent used for the tungsten gapfill CVD process may comprise any combination of the tungsten-containing precursors and reducing agents described in activity 201. In some embodiments, the tungsten-containing precursor comprises WF₆, and the reducing agent comprises H₂.

Here, the tungsten-containing precursor is flowed into the processing region 121 at a rate of between about 50 sccm and about 1000 sccm, or more than about 50 sccm, or less than about 1000 sccm, or between about 100 sccm and about 900 sccm. The reducing agent is flowed into the processing region 121 at a rate of more than about 500 sccm, such as more than about 750 sccm, more than about 1000 sccm, or between about 500 sccm and about 10000 sccm, such as between about 1000 sccm and about 9000 sccm, or between about 1000 sccm and about 8000 sccm.

In some embodiments, the tungsten gapfill CVD process conditions are selected to provide a tungsten feature having a relativity low residual film stress when compared to conventional tungsten CVD processes. For example, in some embodiments, the tungsten gapfill CVD process includes heating the substrate to a temperature of about 250° C. or more, such as about 300° C. or more, or between about 250° C. and about 600° C., or between about 300° C. and about 500° C. During the CVD process, the processing volume 115 is typically maintained at a pressure of less than about 500 Torr, less than about 600 Torr, less than about 500 Torr, less than about 400 Torr, or between about 1 Torr and about 500 Torr, such as between about 1 Torr and about 450 Torr, or between about 1 Torr and about 400 Torr, or for example, between about 1 Torr and about 300 Torr.

In another embodiment, the tungsten gapfill material 308 is deposited at activity 204 using an atomic layer deposition (ALD) process. The tungsten gapfill ALD process includes repeating cycles of alternately exposing the substrate 300 to a tungsten-containing precursor gas and a reducing agent and purging the processing region 121 between the alternating exposures. The tungsten-containing precursor and the reducing agent used for the tungsten gapfill ALD process may comprise any combination of the tungsten-containing precursors and reducing agents described in activity 201. In some embodiments, the tungsten-containing precursor comprises WF₆, and the reducing agent comprises H₂.

Here, the tungsten-containing precursor and the reducing agent are each flowed into the processing region 121 for a duration of between about 0.1 seconds and about 10 seconds, such as between about 0.5 seconds and about 5 seconds. The processing region 121 is typically purged between the alternating exposures by flowing an inert purge gas, such as argon (Ar), into the processing region 121 for a duration of between about 0.1 seconds and about 10 seconds, such as between about 0.5 seconds and about 5 seconds. The purge gas may be delivered from the deposition gas source 140 or from the bypass gas source 138.

Exposing the substrate 300 to the tungsten-containing precursor may include flowing the tungsten-containing precursor into the processing region 121 from the deposition gas source 140 at a flow rate of between about 10 sccm and about 1000 sccm, such as between about 100 sccm and about 1000 sccm, between about 200 sccm and about 1000 sccm, between about 400 sccm and about 1000 sccm, or between about 500 sccm and about 900 sccm. Exposing the substrate 300 to the reducing agent may include flowing the reducing agent into the processing region 121 from the deposition gas source 140 at a flow rate of between about 500 sccm and about 10000 sccm, such as between about 500 sccm and about 8000 sccm, between about 500 sccm and about 5000 sccm, or between about 1000 sccm and about 4000 sccm.

In some embodiments, the tungsten gapfill ALD process includes heating the substrate to a temperature of about 250° C. or more, such as about 300° C. or more, or between about 250° C. and about 600° C., or between about 300° C. and about 500° C. In some embodiments, the ALD process includes maintaining the processing volume 115 at a pressure of less than about 150 Torr, less than about 100 Torr, less than about 50 Torr, for example, less than about 30 Torr, or between about 0.5 Torr and about 50 Torr, such as between about 1 Torr and about 20 Torr.

In other embodiments, the tungsten gapfill material 308 is deposited using a pulsed CVD method that includes repeating cycles of alternately exposing the substrate 300 to a tungsten-containing precursor gas and a reducing agent without purging the processing region 121. The processing conditions for the tungsten gapfill pulsed CVD method may be the same, substantially the same, or within the same ranges as those described above for the tungsten gapfill ALD process.

Beneficially, the tungsten gapfill processes described above provide for a relativity low residual stress in the tungsten material formed therefrom. Without intending to be bound by theory, it is believed that the increased energy provided by the relatively high substrate temperature, e.g., 250° C. or more, increases adatom diffusivity to open adsorption sites while the relativity low processing pressure concurrently slows the tungsten gapfill deposition process. The increased adatom diffusivity and reduced deposition rate facilitate improved (more ordered) atomic arrangement in the deposited tungsten material when compared to conventional conformal CVD processes, beneficially resulting in lower residual film stress in the tungsten gapfill material. For example, in some embodiments, a blanket tungsten layer deposited to a thickness of about 1,200 Å using processing conditions described above has a residual film stress of less than about 1600 MPa, less than about 1500 MPa, less than about 1400 MPa, less than about 1300 MPa, less than about 1200 MPa, less than about 1100 MPa, less than about 1000 MPa, less than about 900 MPa, less than about 800 MPa, less than about 700 MPa, or, in some embodiments, less than about 600 MPa.

In a typical semiconductor manufacturing scheme, a chemical mechanical polishing (CMP) process may be used to remove an overburden of tungsten material (and the barrier layer disposed there below) from the field surface of the substrate following depositing the tungsten gapfill material 308 into the opening 305. CMP processes generally rely on a combination of chemical and mechanical activity to facilitate uniform removal of the overburden layer 310 and an endpoint detection method to determine when the tungsten overburden has cleared from the field surface. Non-uniform clearing of tungsten from the field surface or failure to detect a polishing endpoint can result in undesired over-polishing or under-polishing of at least some regions of the substrate surface. Tungsten over-polishing can cause undesired removal of tungsten from the tungsten feature, e.g., feature coring, because the polishing fluid in a CMP process is often corrosive and can cause damage to the features during over-polishing. Tungsten under-polishing can result in undesired residual tungsten remaining on the field surface following CMP.

Unfortunately, the inhibition treatments used to provide seam-free and void-free tungsten features by promoting bottom-up growth of tungsten also inhibit the growth of tungsten on the field surface to prevent a uniform overburden of tungsten from forming during the bulk tungsten process. Thus, the embodiments herein may include processes for depositing an overburden layer, which are different from the process used to deposit the tungsten gapfill material 308, to provide a uniform thickness of tungsten on the field surface of the substrate desired for subsequent CMP processing.

At activity 205, the method 200 optionally includes forming a second nucleation layer 309 (FIG. 3D) using a second nucleation process. At activity 206, the method 200 includes forming an overburden layer 310 using an overburden process. The second nucleation process and/or the overburden process are used to reduce and/or eliminate the tungsten growth inhibition on the field surface of the substrate, which was provided by the inhibition treatment process at activity 203. By reducing and/or reversing the inhibition effect, the field surface is prepared to allow for the growth and/or deposition of an overburden of tungsten material. The overburden layer 310 may be used to facilitate uniform processing in a subsequent chemical mechanical polishing (CMP) process.

In some embodiments, the second nucleation layer 309 is deposited using an ALD process that is the same or substantially similar to the ALD process used to form the (first) nucleation layer 304 at activity 202, or an ALD process having processing conditions which are in the ranges recited for the ALD process at activity 202. When used, the second nucleation layer 309 may be deposited to a thickness of between about 5 Å and 100 Å, or between about 10 Å and 80 Å, or for example, between about 20 Å and 60 Å.

The process used to deposit the overburden layer 310 at activity 206 may be a CVD or ALD process that is the same or substantially similar to the CVD or ALD process used to deposit the gapfill tungsten material at activity 204, or a process having processing conditions which are in the ranges recited for the processes at activity 202. In other embodiments, the overburden layer is deposited using a CVD process having a processing pressure that is greater than the processing pressure used for the tungsten gapfill process at activity 202. For example, in some embodiments, a ratio of the processing pressure used to deposit the overburden layer 310 to a processing pressure used to deposit the tungsten gapfill material 308 is about 1.25:1 or more, such as about 1.5:1 or more, about 1.75:1 or more, about 2:1 or more, about 2.25:1 or more, about 2.5:1 or more, about 2.75:1 or more, about 3:1 or more, about 3.25:1 or more, or about 3.5:1 or more. The increased processing pressure of the overburden process advantageously results in increased deposition rates and reduced substrate processing time. Here, the overburden layer is deposited to a thickness of between about 500 Å and about 6000 Å, such as between about 1000 Å and about 5000 Å.

At activity 207, the method 200 includes transferring the processed substrate 300 out of the processing chamber 102 and resumes at activity 201 by receiving a to-be-processed substrate thereinto. In some embodiments, the method 200 further includes periodically cleaning the processing chamber 102 between processing substrates by use of the chamber clean process at activity 208. The chamber clean process is used to remove undesirable process residue, e.g., accumulated tungsten residue, from the interior surfaces of the processing volume 115. In some embodiments, the chamber clean process is performed after a number of substrates sequentially processed in the processing chamber 102 is greater than or equal to a threshold value, such as greater than or equal to 2 substrates or more, 3 substrates or more, 5 substrates or more, 7 substrates or more, 9 substrates or more, or 11 substrates or more. In some embodiments, the chamber clean process is performed after every substrate processed in the processing chamber 102.

At activity 208 of the method 200, the chamber clean process generally includes activating a cleaning gas in a remote plasma source, and flowing the activated cleaning gas into the processing chamber 102. Typically, the cleaning gas mixture includes a halogen-containing gas and a carrier gas, such as argon or helium. Examples of suitable halogen-containing gases which may be used in the cleaning gas mixture include NF₃, F₂, SF₆, CL₂, CF₄, C₂F₆, C₄F₈, CHF₃, CF₆, CCl₄, C₂Cl₆, and combinations thereof. In some embodiments, the cleaning gas further comprises a diluent gas, such as Ar, He, or combinations thereof. For example, in one embodiment, the cleaning gas mixture comprises NF₃ and Ar or He. Typically, the activated species of the cleaning gas mixture, e.g., halogen radicals, react with tungsten residue accumulated on surfaces of the processing chamber 102 to form a volatile tungsten species. The volatile tungsten species are evacuated from the processing volume 115 through the exhaust 117.

In some embodiments, a flow rate of the cleaning gas mixture into the remote plasma source, and thus a flow rate of the activated cleaning gas mixture into the processing volume 115, is about 1000 sccm or more, such as about 1500 sccm or more, about 2000 sccm or more, or about 2500 sccm or more. The concentration of halogen-containing gas in the cleaning gas mixture is typically between about 5 vol. % and about 95 vol. %, such as between about 5 vol. % and about 70 vol. %, about 10 vol. % and about 95 vol. %, or more than about 10 vol. %.

In some embodiments, the activated cleaning gas mixture is flowed into the processing volume 115 for a duration of about 5 seconds or more, about 10 seconds or more, about 15 seconds or more.

Here, the chamber clean process is performed using a remote plasma source (e.g., the second radical generator 106B). For example, here, the chamber clean process includes flowing the cleaning gas mixture into the second radical generator 106B, igniting and maintaining a cleaning plasma of the cleaning gas mixture, and flowing the effluent of the cleaning plasma into the processing volume 115. Generally, performing the chamber cleaning operation after each substrate processed in the processing chamber 102 is undesirable due to the lost substrate processing capacity associated therewith. Thus, the chamber cleaning operation is typically performed after a plurality of substrates have been processed in the chamber so that an average number of substrates processed between chamber cleaning operations is about 2 substrates or more, such as about 5 substrates or more, about 10 substrates or more, about 15 substrates or more, or about 20 substrates or more. In some embodiments, the chamber clean process is performed after every substrate processed in the processing chamber 102.

The use of a dedicated plasma source (first radical generator 106A) for the inhibition treatment process at activity 203 desirably provides for improved processing stability for the inhibition treatments over the use of a common plasma source for both the inhibition treatment process and chamber cleaning process. This is likely because a plasma formed from the treatment gas is substantially less corrosive than a plasma formed from a halogen-based cleaning gas, and thus, ion-based damage to surfaces within the first radical generator 106A is relativity low. Nonetheless, in time at least some drift in processing performance at the substrate edge, e.g., a degradation of inhibition performance at the substrate edge, has been observed when using a treatment plasma source dedicated to forming nitrogen treatment radicals.

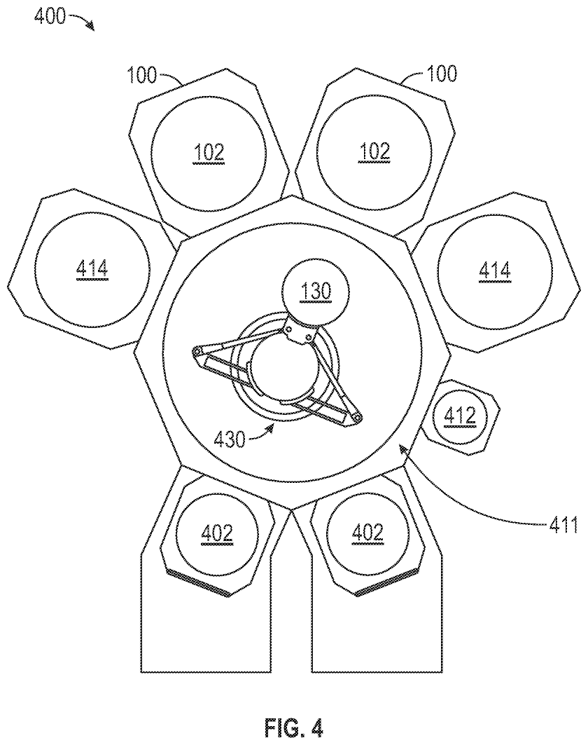

In some embodiments, the methods described above may be performed using a multi-chamber processing system 400, such as illustrated in FIG. 4. Here, the multi-chamber processing system 400 includes a plurality of system loading stations, here load lock stations 402, for receiving substrates. The load lock stations 402 may be sealed and are typically coupled to a vacuum, such as one or more vacuum pumps, which may be used to evacuate gases therefrom and maintain the load lock stations 402 at sub-atmospheric conditions. A substrate handler 430, disposed in a transfer chamber 411, is used to move substrates 130 between the load lock stations 402, one or more processing chambers 414, 102, and an optional cool down chamber 412. Each processing chamber 414 may be configured to perform at least one of a substrate deposition process, such as cyclical layer deposition (CLD), atomic layer deposition (ALD), chemical vapor deposition (CVD), physical vapor deposition (PVD), etch, degas, pre-cleaning orientation, anneal, and other substrate processes. In one embodiment, the processing chamber 414 is the same as the processing chamber 102. Each of the processing chambers 414, 102, may include the processing system 100 as described in FIGS. 1A-1B and may be configured to perform the tungsten gapfill processing schemes described herein.

Advantageously, the processing systems 100, 400 described above are configured to accommodate the different processing conditions desired for each of the nucleation, inhibition, gapfill deposition, and overburden deposition processes within a single processing chamber 102 without removing the substrate therefrom. The processing systems 100 are further configured to reduce processing variability, e.g., within-substrate processing non-uniformity and substrate-to-substrate processing variation, thus providing for desirably wider processing windows to achieve void-free, seam-free or low-stress tungsten features.

The term “coupled” is used herein to refer to the direct or indirect coupling between two objects. For example, if object A physically touches object B and object B touches object C, the objects A and C may still be considered coupled to one another-even if objects A and C do not directly physically touch each other. For instance, a first object may be coupled to a second object even though the first object is never directly in physical contact with the second object.

While the foregoing is directed to embodiments of the present disclosure, other and further embodiments of the disclosure may be devised without departing from the basic scope thereof, and the scope thereof is determined by the claims that follow.

What is claimed is:

1. A substrate processing system, comprising:
a processing chamber, comprising a chamber lid assembly, one or more chamber sidewalls, and a chamber base that collectively define a processing volume;
a gas delivery system fluidly coupled to the processing chamber, the gas delivery system comprising a first radical generator and a second radical generator; and
a non-transitory computer readable medium having instructions stored thereon for performing a method of processing a plurality of substrates when executed by one or more processors, the method comprising:
(a) receiving a substrate into the processing volume;
(b) forming a first tungsten nucleation layer on the substrate;
(c) exposing the substrate to an activated treatment gas, the activated treatment gas comprising an effluent of a treatment plasma formed in the first radical generator, wherein the treatment plasma is formed of a halogen-free gas and a halogen-containing gas;
(d) exposing the substrate to a first tungsten-containing precursor and a first reducing agent to deposit a tungsten gapfill material; and
(e) transferring the substrate out of the processing volume.

2. The substrate processing system of claim 1, the method further comprising:
(f) exposing chamber surfaces in the processing volume to an activated cleaning gas, the activated cleaning gas comprising an effluent of a cleaning plasma formed in the second radical generator; and
(g) repeating (a)-(f).

3. The substrate processing system of claim 2, wherein the halogen-free gas comprises nitrogen.

4. The substrate processing system of claim 3, wherein a flow rate of the halogen-free gas is equal to or less than about 50 sccm.

5. The substrate processing system of claim 2, wherein the halogen-containing gas comprises NF₃.

6. The substrate processing system of claim 5, wherein a flow rate of the halogen-containing gas is less than about 3 sccm.

7. The substrate processing system of claim 1, wherein the treatment plasma further comprises an inert gas.

8. The substrate processing system of claim 7, wherein the inert gas is Ar.

9. The substrate processing system of claim 1, wherein the substrate comprises a material layer having a plurality of openings formed therein; and exposing the substrate to the activated treatment gas differentially inhibits tungsten deposition on a field surface of the substrate relative to surfaces within the plurality of openings.

10. The substrate processing system of claim 1, wherein forming the first tungsten nucleation layer comprises repeating cycles of alternately exposing the substrate to the first or a second tungsten-containing precursor and the first or a second reducing agent.

11. A gas delivery system for processing a substrate, comprising:
a first radical generator and a second radical generator; and
a non-transitory computer readable medium having instructions stored thereon for performing a method of processing a plurality of substrates when executed by one or more processors, the method comprising:
(a) receiving a substrate into a processing volume of a processing chamber fluidly coupled to the gas delivery system;
(b) forming a first tungsten nucleation layer on the substrate;
(c) exposing the substrate to an activated treatment gas, the activated treatment gas comprising an effluent of a treatment plasma formed in the first radical generator, wherein the treatment plasma is formed of a substantially halogen-free gas and a halogen-containing gas;
(c) exposing the substrate to a first tungsten-containing precursor and a first reducing agent to deposit a tungsten gapfill material; and
(d) transferring the substrate out of the processing volume.

12. The gas delivery system of claim 11, wherein the substantially halogen-free gas comprises nitrogen.

13. The gas delivery system of claim 12, wherein the treatment plasma is further formed from an inert gas.

14. The gas delivery system of claim 13, the method of processing a plurality of substrates further comprising:
before (c), forming a conformal tungsten layer on the first tungsten nucleation layer; and
forming a second tungsten nucleation layer on the conformal tungsten layer.

15. A method of processing a substrate, comprising:
(a) receiving the substrate into a processing volume of a processing chamber
(b) forming a first tungsten nucleation layer on the substrate;
(c) exposing the substrate to an activated treatment gas, the activated treatment gas comprising an effluent of a treatment plasma formed of a halogen-free gas and a halogen-containing gas; and
(d) exposing the substrate to a first tungsten-containing precursor and a first reducing agent.

16. The method of claim 15, further comprising:
(e) transferring the substrate out of the processing volume;
(f) exposing chamber surfaces in the processing volume to an activated cleaning gas; and
(g) repeating (a)-(f).

17. The method of claim 16, wherein the halogen-free gas comprises nitrogen.

18. The method of claim 17, wherein a flow rate of the halogen-containing gas is less than about 3 sccm.

19. The method of claim 15, wherein the treatment plasma further comprises an inert gas.

20. The method of claim 19, wherein
the substrate comprises a material layer having a plurality of openings formed therein, and
exposing the substrate to the activated treatment gas differentially inhibits tungsten deposition on a field surface of the substrate relative to surfaces within the plurality of openings.
